(19) United States
(12) Patent Application Publication
(10) Pub. No.: US 2005/0045897 A1
(43) Pub. Date: Mar. 3, 2005

(54) Light emitting apparatus

(76) Inventors: Shen-Hong Chou, Kaohsiung City (TW); Pang-Hsuan Liu, Longtan Township (TW)

Correspondence Address: RABIN & Berdo, PC, 1101 14TH STREET, NW, SUITE 500, WASHINGTON, DC, 20005, US

(21) Appl. No.: 10/841,463

(22) Filed: May 10, 2004

(30) Foreign Application Priority Data
Aug. 27, 2003 (TW) 92123672

(51) Int. Cl. H01L 29/20; H01L 33/00

(52) U.S. Cl. 257/98; 257/99; 257/89

(57) ABSTRACT

A light emitting apparatus at least includes a circuit board, several light emitting diodes (LEDs), a first reflective substance, and a diffusion structure. The LEDs, including red (R), green (G), and blue (B) LEDs, are disposed on the circuit board and connected therewith, and the first reflective substance is disposed on the circuit board and having a plurality of cavities for the LEDs. The diffusion structure is disposed on the circuit board and covering the LEDs. The diffusion structure includes several indentations, a transparent main body and several diffusion beads. The indentations are formed on a bottom surface of the diffusion structure and face the LEDs to accommodate the LEDs. The diffusion beads are dispersed in the transparent main body and diffuse light emitted from the LEDs so that light emitted from R/G/B LEDs can be mixed into white light more sufficiently through the diffusion structure.

This application claims the benefit of Taiwan application Serial No. 092123672, filed Aug. 27, 2003, the subject matter of which is incorporated herein by reference.

### BACKGROUND OF THE INVENTION

1. Field of the Invention

The invention relates in general to a light emitting apparatus, and more particularly to a light emitting apparatus that mix light emitted from red (R), green (G) and blue (B) light emitting diode into white light more sufficiently.

2. Description of the Related Art

A light-emitting diode (LED) is a semiconductor device that emits visible light when an electric current passes through it. The light is not particularly bright, but in most LEDs it is monochromatic, occurring at a single wavelength. The output from an LED can range from red (at a wavelength of approximately 700 nanometers) to blue-violet (about 400 nanometers). For example, LEDs which emit red (R) rays are known as R LEDs, LEDs which emit green (G) rays are known as G LEDs, and LEDs which emit blue (B) rays are known as B LEDs. LEDs possessing of a variety of advantages such as low power requirement, high efficiency and long life are well known and have typical applications including indicator lights, LCD panel backlighting, fiber optic data transmission, remote controls and optoisolators.

FIG. 1 is a cross-sectional view showing a portion of a conventional liquid crystal display. Referring to FIG. 1, a liquid crystal display (LCD) 10 at least includes a LCD panel 14 and a light emitting apparatus 15. The light emitting apparatus 15 at least includes a printed circuit board (PCB) 11, several light emitting diodes (LEDs) 12, and a diffuser plate 13. The LEDs 12 include several red (R), green (G), and blue (B) LEDs and all LEDs 12 are disposed on the PCB 11 as arrays and are electrically connected with the PCB 11.

Red rays, green rays or blue rays are provided by the LEDs 12 in accordance with the R/G/B LEDs thereof, and then the red rays, green rays and blue rays are all guided through the diffuser plate 13. Next, the red rays, green rays and blue rays are mixed into white light after passing through the diffuser plate 13, and then the white light can be emitted to the LCD panel 14.

However, consideration should be given here to the light-mixing effect of the conventional light emitting apparatus 15. Conventionally, the distance between the LEDs 12 and the diffuser plate 13 is too short to offer long route for light. That causes color divergence of the LCD panel 14 and consequentially the optical quality of the LCD 10 is greatly influenced. Also, the diffuser plate 13 could bend and deform easily because the diffuser plate 13 is not attached to any other rigid components of the light emitting apparatus 15. This is another disadvantage of a conventional display.

### SUMMARY OF THE INVENTION

In view of the foregoing, it is an object of the present invention to provide an improved light emitting apparatus with better light-mixing effect in order to prevent the deflection, bend, or deformation of a conventional diffuser plate.

An object of the present invention is to provide a light emitting apparatus at least including a circuit board, several light emitting diodes (LEDs), a first reflective substance, and a diffusion structure. The LEDs, including red (R), green (G), and blue (B) LEDs, are disposed on the circuit board and connected therewith, and the first reflective substance is disposed on the circuit board and having several cavities for the LEDs. The diffusion structure is disposed on the circuit board and covering the LEDs. The diffusion structure includes several indentations, a transparent main body and several diffusion beads. The indentations are formed on a bottom surface of the diffusion structure and face the LEDs to accommodate the LEDs. The diffusion beads are dispersed in the transparent main body and diffuse light emitted from the LEDs so that light emitted from R/G/B LEDs can be mixed into white light more sufficiently through the diffusion structure.

Another object of the present invention is to provide a light emitting apparatus at least including a PCB, several R/G/B LEDs, a first reflective substance, and a diffusion structure. The R/G/B LEDs are disposed on the PCB and connected with the PCB. The first reflective substance is disposed on the PCB and having several cavities for the R/G/B LEDs. The diffusion structure is disposed on the PCB and covering the R/G/B LEDs. The diffusion structure includes several indentations, a transparent main body and several diffusion beads. The indentations are formed on a bottom surface of the diffusion structure and face the R/G/B LEDs to accommodate all LEDs. The diffusion beads are dispersed in the transparent main body made of PMMA or glass, and diffuse light emitted from the R/G/B LEDs so that light emitted from R/G/B LEDs can be mixed into white light more sufficiently through the diffusion structure.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a cross-sectional view showing a portion of a conventional liquid crystal display;

FIG. 2 is a cross-sectional view of a light emitting apparatus according to the first example in the preferred embodiment of the invention;

FIG. 3 is a stereographic view of a diffusing structure in FIG. 2;

FIG. 4 is a cross-sectional view of a light emitting apparatus according to the second example in the preferred embodiment of the invention; and

FIG. 5 is a cross-sectional view of a light emitting apparatus according to the third example in the preferred embodiment of the invention.

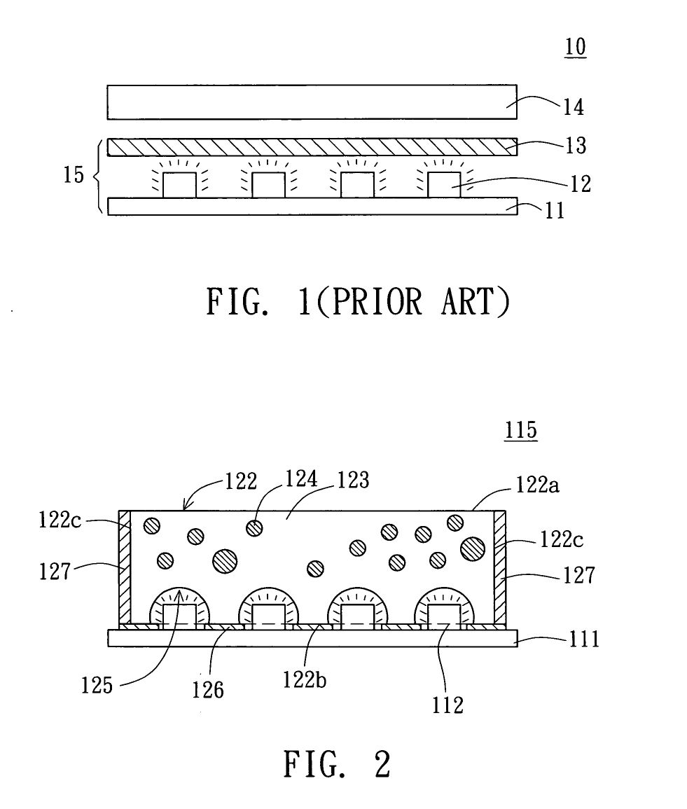

### DETAILED DESCRIPTION OF THE INVENTION

The present invention will be described more fully hereinafter with reference to the accompanying drawings, in which preferred embodiments of the invention are shown. This invention may, however, be embodied in many different forms and should not be construed as limited to the embodiments set forth herein; rather, three examples are provided so that this disclosure will be thorough and complete, and will fully convey the scope of the invention to those skilled in the art. Like numbers refer to like components throughout.

### EXAMPLE 1

FIG. 2 is a cross-sectional view of a light emitting apparatus according to the first example in the preferred embodiment of the invention. Referring to FIG. 2, a light emitting apparatus 115 at least includes a circuit board 111, several light emitting diodes (LEDs) 112, a diffusion structure 122, a first reflective substance 126 and at least one second reflective substance 127. The circuit board 111 is preferably a printed circuit board (PCB) and the LEDs 112 include several red (R), green (G), and blue (B) LEDs. All LEDs 112 are disposed on the circuit board 111 and electrically connected with the circuit board 111.

The first reflective substance 126 is disposed on the circuit board 111 and there are several cavities formed therein so that portions of the circuit board 111 are exposed. The first reflective substance 126 can be disposed on a surface of the circuit board 111 by coating, and then the LEDs 112 are positioned on the exposed circuit board 111 and are joined with solder. Or, the first reflective substance 126 can be disposed on the surface of the circuit board 111 by sticking with paste after the LEDs 112 are separately positioned at several predetermined sites on the circuit board 111 by being joined with solder. Besides, the material of the first reflective substance 126 is preferably polyethylene terephthalate (PET).

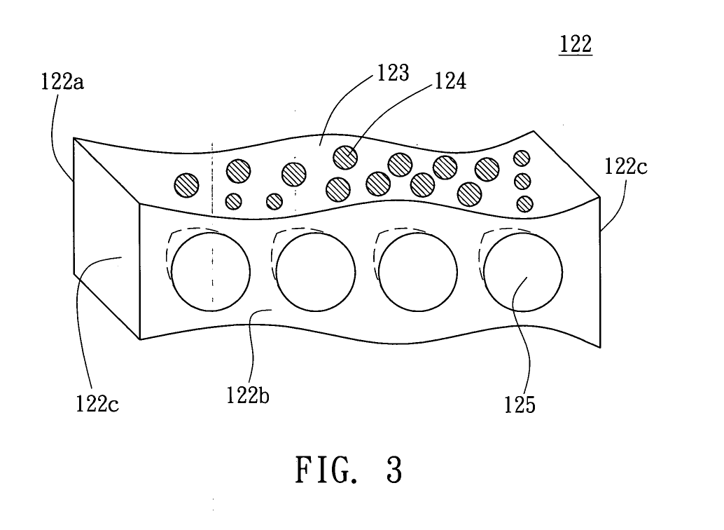

FIG. 3 is a stereographic view of a diffusing structure in FIG. 2. Both referring to FIG. 2 and FIG. 3, the diffusion structure 122 is disposed on the circuit board 111 and covering the LEDs 112. The diffusion structure 122 includes several indentations 125, a transparent main body 123 and several diffusion beads 124. The indentations 125 are formed on a bottom surface 122b of the diffusion structure 122 and face the LEDs 112 to accommodate the LEDs 112. The indentations 125 can be hemisphere-shaped or bowl-shaped, as shown in FIG. 2.

The diffusion beads 124 are dispersed in the transparent main body 123 and various sizes and shapes of the diffusion beads 124 are acceptable. The transparent main body 123 and the diffusion beads 124 can be preferably made by injection molding. The material of the transparent main body 123 is preferably polymethyl methacrylate (PMMA) or glass. The refractive index of the diffusion beads 124 is preferably about 1.4 to 2 and the material of the diffusion beads 124 is preferably silicon dioxides (SiO₂).

The second reflective substances 127 can be disposed on two opposite side surfaces 122c of the diffusion structure 122 on the circuit board 111 by coating or by sticking with paste. Besides, the material of the second reflective substance 127 is preferably polyethylene terephthalate (PET).

Red rays, green rays or blue rays are provided by the LEDs 112 in accordance with the R/G/B LEDs thereof, then the red rays, green rays and blue rays are all guided through the indentations 125 and into the diffusion structure 122. The indentations 125 function as divergent lens, so that the disperse angle of the light emitted from the R/G/B LEDs 112 is increased and the light divergency is enhanced. Further, the diffusion beads 124 diffuse the red rays, green rays and blue rays when the three rays are emitted to surface of the diffusion beads 124, and then the red rays, green rays and blue rays originating from the LEDs 112 are mixed into white light more sufficiently by the diffusion beads 124 of the diffusion structure 122. Finally, the white light is emitted out of the diffusion structure 122 from a top surface 122a of the diffusion structure 122.

One of the characteristics of the invention is that the diffusion structure 122 provides a good light-mixing effect instead of the conventional diffuser plate 13. Also, portions of the diffusion structure 122 are directly connected with the circuit board 111, so that the conventional problems, such as deflection, bend, or deformation of the diffuser plate 13, are prevented.

### EXAMPLE 2

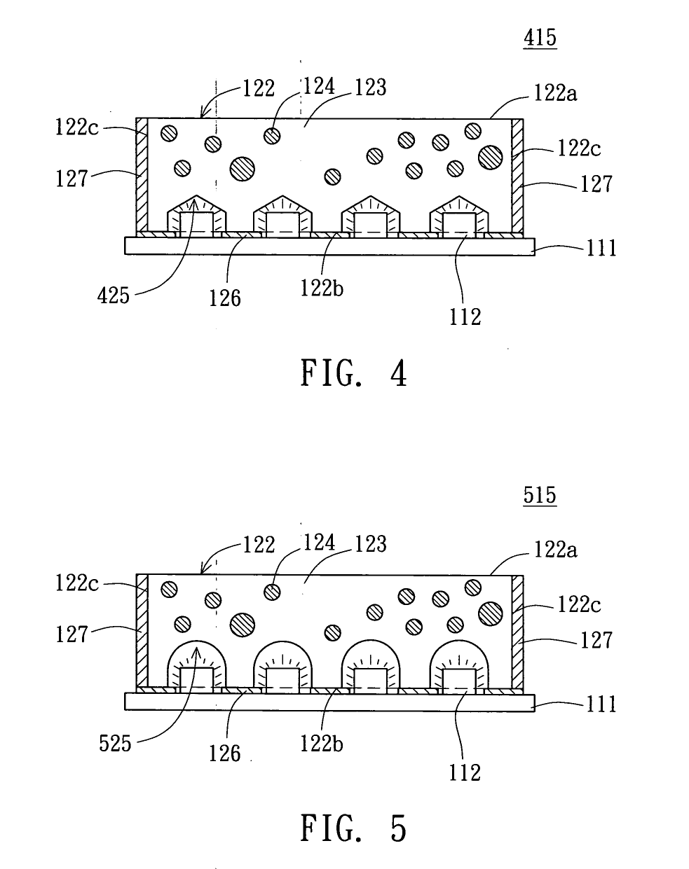

FIG. 4 is a cross-sectional view of a light emitting apparatus according to the second example in the preferred embodiment of the invention. Referring to FIG. 4, a light emitting apparatus 415 at least includes a circuit board 111, several light emitting diodes (LEDs) 112, a diffusion structure 122, a first reflective substance 126 and at least one second reflective substance 127. Most components of the light emitting apparatus 415 here are similar to the ones of the light emitting apparatus 115 in the first example. One difference between the light emitting apparatus 415 and the light emitting apparatus 115 is the configuration of the indentations of the diffusion structure. In this example, the diffusion structure 122 includes several indentations 425 and the indentations 425 are awl-shaped, as shown in FIG. 4.

### EXAMPLE 3

FIG. 5 is a cross-sectional view of a light emitting apparatus according to the third example in the preferred embodiment of the invention. Referring to FIG. 5, a light emitting apparatus 515 at least includes a circuit board 111, several light emitting diodes (LEDs) 112, a diffusion structure 122, a first reflective substance 126 and at least one second reflective substance 127. Most components of the light emitting apparatus 515 here are similar to the ones of the light emitting apparatus 115 in the first example. One difference between the light emitting apparatus 515 and the light emitting apparatus 115 is the configuration of the indentations of the diffusion structure. In this example, the diffusion structure 122 includes several indentations 525. The indentations 525 are oval-shaped and the cross section of the indentations 525 is an elliptic cylinder, as shown in FIG. 5.

In summary, the light emitting apparatuses 115, 415, 515 of the present invention at least offer the following advantages:

(1). The diffusion structure 122 of the invention can provide a better light-mixing effect than the conventional diffuser plate 13.

(2). Also, the conventional problems, such as deflection, bend, or deformation of the diffuser plate 13, are prevented because portions of the diffusion structure 122 are directly connected with the circuit board 111.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A light emitting apparatus, at least comprising:
a circuit board;
a plurality of light emitting diodes (LEDs), disposed on the circuit board and connected therewith;
a first reflective substance, disposed on the circuit board and having a plurality of cavities for the LEDs; and
a diffusion structure, disposed on the circuit board and covering the LEDs, wherein the diffusion structure comprises a plurality of indentations, a transparent main body and a plurality of diffusion beads; the indentations are formed on a bottom surface of the diffusion structure and face the LEDs to accommodate the LEDs; the diffusion beads are dispersed in the transparent main body and diffuse light emitted from the LEDs.

2. The light emitting apparatus according to claim 1, wherein the material of the transparent main body is polymethyl methacrylate (PMMA) or glass.

3. The light emitting apparatus according to claim 1, wherein the refractive index of the diffusion beads is about 1.4 to 2.

4. The light emitting apparatus according to claim 1, wherein the first reflective substance is disposed on the circuit board by coating or by sticking with paste.

5. The light emitting apparatus according to claim 1, wherein the material of the first reflective substance is polyethylene terephthalate (PET).

6. The light emitting apparatus according to claim 1, wherein the light emitting apparatus further comprises a second reflective substance disposed on a side surface of the diffusion structure.

7. The light emitting apparatus according to claim 6, wherein the second reflective substance is disposed on the diffusion structure by coating or by sticking with paste.

8. The light emitting apparatus according to claim 6, wherein the material of the second reflective substance is PET.

9. The light emitting apparatus according to claim 1, wherein the circuit board is a printed circuit board (PCB).

10. The light emitting apparatus according to claim 1, wherein the transparent main body and the diffusion beads are made by injection molding.

11. The light emitting apparatus according to claim 1, wherein the indentations are hemisphere-shaped or bowl-shaped.

12. The light emitting apparatus according to claim 1, wherein the LEDs comprises a plurality of red (R), green (G), and blue (B) LEDs.

13. A light emitting apparatus, at least comprising:
a PCB;
a plurality of R/G/B LEDs, disposed on the PCB and connected therewith;
a first reflective substance, disposed on the PCB and having a plurality of cavities for the R/G/B LEDs; and
a diffusion structure, disposed on the PCB and covering the R/G/B LEDs, wherein the diffusion structure comprises a plurality of indentations, a transparent main body and a plurality of diffusion beads; the indentations are formed on a bottom surface of the diffusion structure and face the R/G/B LEDs to accommodate all LEDs; the diffusion beads are dispersed in the transparent main body made of PMMA or glass, and diffuse light emitted from the R/G/B LEDs.

14. The light emitting apparatus according to claim 13, wherein the refractive index of the diffusion beads is about 1.4 to 2.

15. The light emitting apparatus according to claim 13, wherein the first reflective substance is disposed on the PCB by coating or by sticking with paste.

16. The light emitting apparatus according to claim 13, wherein the transparent main body and the diffusion beads are made by injection molding.

17. The light emitting apparatus according to claim 13, wherein the material of the first reflective substance is PET.

18. The light emitting apparatus according to claim 13, wherein the light emitting apparatus further comprises a second reflective substance disposed on a side surface of the diffusion structure.

19. The light emitting apparatus according to claim 18, wherein the second reflective substance is disposed on the diffusion structure by coating or by sticking with paste.

20. The light emitting apparatus according to claim 18, wherein the material of the second reflective substance is PET.

21. The light emitting apparatus according to claim 13, wherein the indentations are hemisphere-shaped or bowl-shaped.
